(19) United States
(12) Patent Application Publication
(10) Pub. No.: US 2025/0220903 A1
(43) Pub. Date: Jul. 3, 2025

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Changhee LEE, Suwon-si (KR); Sang-Yong PARK, Suwon-si (KR); Dajin Kim, Suwon-si (KR); Sang-Hoon KIM, Suwon-si (KR); Seung Jae BAIK, Suwon-si (KR); Jaeduk LEE, Suwon-si (KR); Chulmin CHOI, Suwon-si (KR)

(73) Assignee: SAMSUNG ELECTRONICS CO., LTD., Suwon-si (KR)

(21) Appl. No.: 18/891,769

(22) Filed: Sep. 20, 2024

(30) Foreign Application Priority Data
Dec. 29, 2023 (KR) 10-2023-0195967

(51) Int. Cl. H10B 43/27; H10B 43/35

(52) U.S. Cl. CPC H10B 43/27; H10B 43/35

(57) ABSTRACT

A three-dimensional (3D) semiconductor memory device includes a substrate, a stack on the substrate, the stack including gate electrodes stacked in a first direction perpendicular to a bottom surface of the substrate, a cell vertical structure penetrating the stack and extending in the second direction, a source layer on a top surface of the stack, a back-gate electrode in the cell vertical structure and extending in the first direction, and a channel pad at a level lower than a bottom surface of the source layer and enclosed by the cell vertical structure, where the back-gate electrode is spaced apart from the channel pad.

### CROSS-REFERENCE TO RELATED APPLICATIONS

This application is based on and claims priority under 35 U.S.C. § 119 to Korean Patent Application No. 10-2023-0195967, filed on Dec. 29, 2023, in the Korean Intellectual Property Office, the disclosure of which is incorporated by reference herein in its entirety.

### BACKGROUND

The present disclosure relates to a three-dimensional (3D) semiconductor memory device and an electronic system including the same.

A semiconductor device capable of storing a large amount of data is required as a data storage of an electronic system. Higher integration of semiconductor devices is required to satisfy consumer demands for large data storing capacity, superior performance, and inexpensive prices. In the case of two-dimensional or planar semiconductor devices, integration is mainly determined by the area occupied by a unit memory cell, and thus integration is greatly influenced by the level of a fine pattern forming technology. However, the extremely expensive process equipment needed to increase pattern fineness sets a practical limitation on increasing integration for two-dimensional or planar semiconductor devices.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Example embodiments provide a three-dimensional (3D) semiconductor memory device which may have improved reliability and an electronic system including the same.

Additional aspects will be set forth in part in the description which follows and, in part, will be apparent from the description, or may be learned by practice of the presented embodiments.

According to an aspect of an example embodiment, a 3D semiconductor memory device may include a substrate, a stack on the substrate, the stack including gate electrodes stacked in a first direction perpendicular to a bottom surface of the substrate, a cell vertical structure penetrating the stack and extending in the first direction, a source layer on a top surface of the stack, a back-gate electrode in the cell vertical structure and extending in the first direction, and a channel pad at a level lower than a bottom surface of the source layer and enclosed by the cell vertical structure, where the back-gate electrode is spaced apart from the channel pad.

According to an aspect of an example embodiment, a 3D semiconductor memory device may include a substrate, a stack on the substrate, the stack including gate electrodes stacked in a first direction perpendicular to a bottom surface of the substrate, a cell vertical structure penetrating the stack and extending in the first direction, a back-gate electrode in the cell vertical structure and extending in the first direction, a back-gate contact that contacts a top surface of the back-gate electrode, and a bit line at a level lower than a bottom surface of the back-gate electrode.

According to an aspect of an example embodiment, an electronic system may include a 3D semiconductor memory device, and a controller connected to the three-dimensional semiconductor memory device through an input/output pad and configured to control the three-dimensional semiconductor memory device, where the 3D semiconductor memory device may include a substrate, a stack including gate electrodes stacked in a first direction perpendicular to a bottom surface of the substrate, a cell vertical structure penetrating the stack and extending in the first direction, a source layer on a top surface of the stack, a back-gate electrode in the cell vertical structure and extending in the first direction, and a channel pad at a level lower than a bottom surface of the source layer and enclosed by the cell vertical structure, where the back-gate electrode is spaced apart from the channel pad.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1A is a diagram illustrating an electronic system including a three-dimensional (3D) semiconductor memory device according to one or more embodiments;

FIG. 1B is a diagram illustrating an electronic system including a 3D semiconductor memory device according to one or more embodiments;

FIG. 2 is a perspective view illustrating an electronic system including a 3D semiconductor memory device according to one or more embodiments;

FIG. 3 is a cross-sectional view taken along a line I-I′ of FIG. 2, illustrating a semiconductor package including a semiconductor device according to one or more embodiments;

FIG. 4 is a cross-sectional view taken along a line II-II′ of FIG. 2, illustrating a semiconductor package including a semiconductor device according to one or more embodiments;

FIG. 5 is a plan view illustrating a 3D semiconductor memory device according to one or more embodiments;

FIG. 6 is a cross-sectional view taken along a line A-A′ of FIG. 5 according to one or more embodiments;

FIG. 7 is an enlarged view illustrating a portion ‘P1’ of FIG. 6 according to one or more embodiments;

FIG. 8A is a diagram illustrating a voltage condition for a programming operation on a 3D semiconductor memory device, according to one or more embodiments;

FIG. 8B is a diagram illustrating a programming operation on a 3D semiconductor memory device, according to one or more embodiments;

FIG. 9A is a diagram illustrating a voltage condition for a reading operation on a 3D semiconductor memory device according to one or more embodiments;

FIG. 9B is a diagram illustrating a reading operation on a 3D semiconductor memory device according to one or more embodiments;

FIG. 10 is a cross-sectional view along a line of a semiconductor memory device that corresponds to the line A-A′ of FIG. 5 according to one or more embodiments;

FIGS. 11 to 16 are cross-sectional views illustrating a method of fabricating a 3D semiconductor memory device, according to one or more embodiments; and

FIGS. 17 to 20 are cross-sectional views illustrating a method of fabricating a 3D semiconductor memory device, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

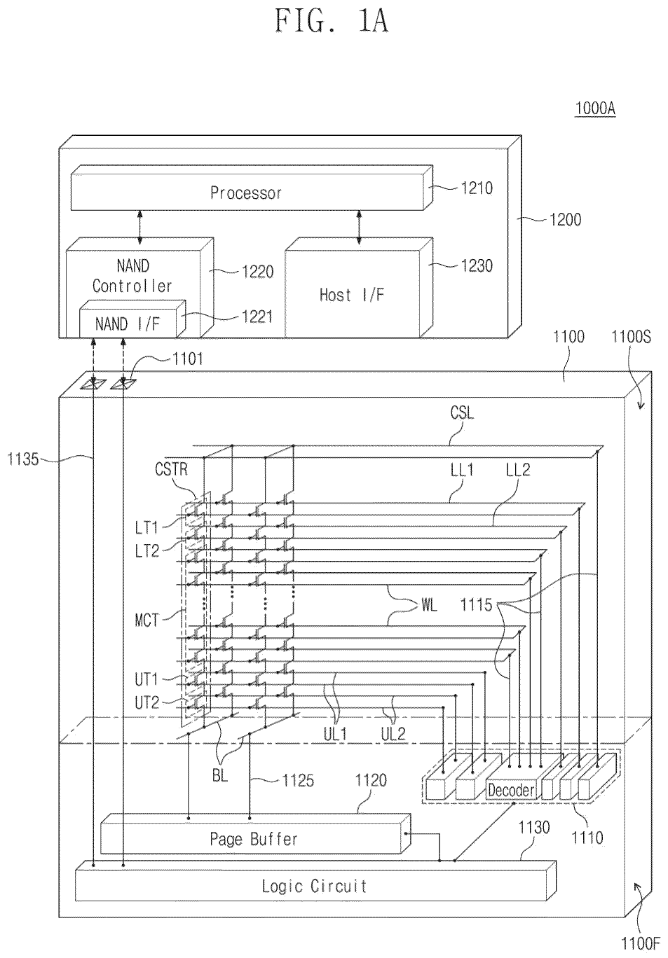

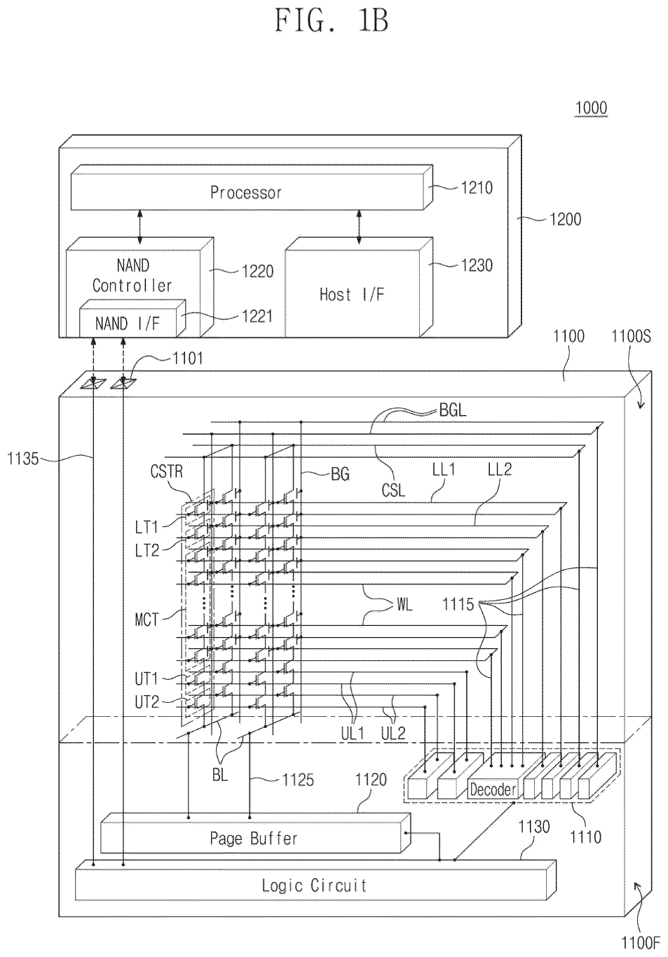

FIG. 1A is a diagram illustrating an electronic system including a three-dimensional (3D) semiconductor memory device according to one or more embodiments.

Referring to FIG. 1A, an electronic system 1000A may include a 3D semiconductor memory device 1100 and a controller 1200, which are electrically connected to each other. The electronic system 1000A may be a storage device including one or more 3D semiconductor memory devices 1100 or an electronic device including the storage device. For example, the electronic system 1000A may be a solid state drive (SSD) device, a universal serial bus (USB), a computing system, a medical system, or a communication system, in which at least one 3D semiconductor memory device 1100 is provided.

The 3D semiconductor memory device 1100 may be a nonvolatile memory device (e.g., a 3D NAND FLASH memory device to be described below). The 3D semiconductor memory device 1100 may include a first region 1100F and a second region 1100S on the first region 1100F. However, the first region 1100F may be disposed beside the second region 1100S. The first region 1100F may be a peripheral circuit region, which includes a decoder circuit 1110, a page buffer 1120, and a logic circuit 1130. The second region 1100S may be a memory cell region, which includes bit lines BL, a common source line CSL, word lines WL, first lines LL1 and LL2, second lines UL1 and UL2, and memory cell strings CSTR between the bit lines BL and the common source line CSL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed according to one or more embodiments. The memory cell strings CSTR may be placed between the common source line CSL and the first region 1100F.

In one or more embodiments, the second transistors UT1 and UT2 may include string selection transistors, and the first transistors LT1 and LT2 may include ground selection transistors. The first lines LL1 and LL2 may be used as gate electrodes of the first transistors LT1 and LT2. The word lines WL may be used as gate electrodes of the memory cell transistors MCT, and the second lines ULI and UL2 may be used as gate electrodes of the second transistors UT1 and UT2.

In one or more embodiments, the first transistors LT1 and LT2 may include a first erase control transistor LT1 and a ground selection transistor LT2, which are connected in series. For example, the second transistors UT1 and UT2 may include a string selection transistor UT1 and a second erase control transistor UT2, which are connected in series. In one or more embodiments, at least one of the first and second erase control transistors LT1 and UT2 may be used for an erase operation of erasing data, which are stored in the memory cell transistors MCT, using a gate-induced drain leakage (GIDL) phenomenon, but embodiments are not limited to this example.

The common source line CSL, the first lines LLI and LL2, the word lines WL, and the second lines UL1 and UL2 may be electrically connected to the decoder circuit 1110 through first interconnection lines 1115, which extend from the first region 1100F to the second region 1100S. The bit lines BL may be electrically connected to the page buffer 1120 through second connection lines 1125, which extend from the first region 1100F to the second region 1100S.

In the first region 1100F, the decoder circuit 1110 and the page buffer 1120 may be configured to perform a control operation, which is performed on at least one memory cell transistor selected from the memory cell transistors MCT. The decoder circuit 1110 and the page buffer 1120 may be controlled by the logic circuit 1130. The 3D semiconductor memory device 1100 may communicate with the controller 1200 through an input/output pad 1101, which is electrically connected to the logic circuit 1130. The input/output pad 1101 may be electrically connected to the logic circuit 1130 through an input/output interconnection line 1135, which is extended from the first region 1100F to the second region 1100S.

The controller 1200 may include a processor 1210, a NAND controller 1220, and a host interface 1230 (shown as “I/F” in the figures). In one or more embodiments, the electronic system 1000A may include a plurality of 3D semiconductor memory devices 1100, which are controlled by the controller 1200.

The processor 1210 may control overall operations of the electronic system 1000A including the controller 1200. Based on a specific firmware, the processor 1210 may execute operations of controlling the NAND controller 1220 and accessing the 3D semiconductor memory device 1100. The NAND controller 1220 may include a NAND interface 1221, which is used for communication with the 3D semiconductor memory device 1100. The NAND interface 1221 may be used to transmit and receive control commands to control the 3D semiconductor memory device 1100, commands for data to be written in or read from the memory cell transistors MCT of the 3D semiconductor memory device 1100, and so forth. The host interface 1230 may be configured to allow for communication between the electronic system 1000A and an external host. If a control command is provided from an external host through the host interface 1230, the processor 1210 may control the 3D semiconductor memory device 1100 in response to the control command.

FIG. 1B is a diagram illustrating an electronic system including a 3D semiconductor memory device according to one or more embodiments.

Referring to FIG. 1B, an electronic system 1000, which includes a 3D semiconductor memory device according to one or more embodiments, may include the same or similar elements as those in the electronic system 1000A described with reference to FIG. 1A.

Alternately, the second region 1100S of the electronic system may further include a back-gate line BGL. Furthermore, in the second region 1100S, each of the memory cell strings CSTR may further include a back-gate electrode BG, which is adjacent to the first transistors LT1 and LT2 and the memory cell transistors MCT in a horizontal direction. In one or more embodiments, the back-gate electrode BG may be provided at a level that is higher than the second transistors UT1 and UT2, in the memory cell string CSTR.

In one or more embodiments, the back-gate electrode BG may be electrically connected to the back-gate line BGL through an additional contact, but embodiments are not limited thereto.

The back-gate line BGL may be electrically connected to the decoder circuit 1110 through the first interconnection lines 1115, which extend from the first region 1100F to the second region 1100S.

The back-gate electrode BG and the back-gate line BGL may be spaced apart from, and electrically disconnected from, the common source line CSL, the bit lines BL, and the word line WL.

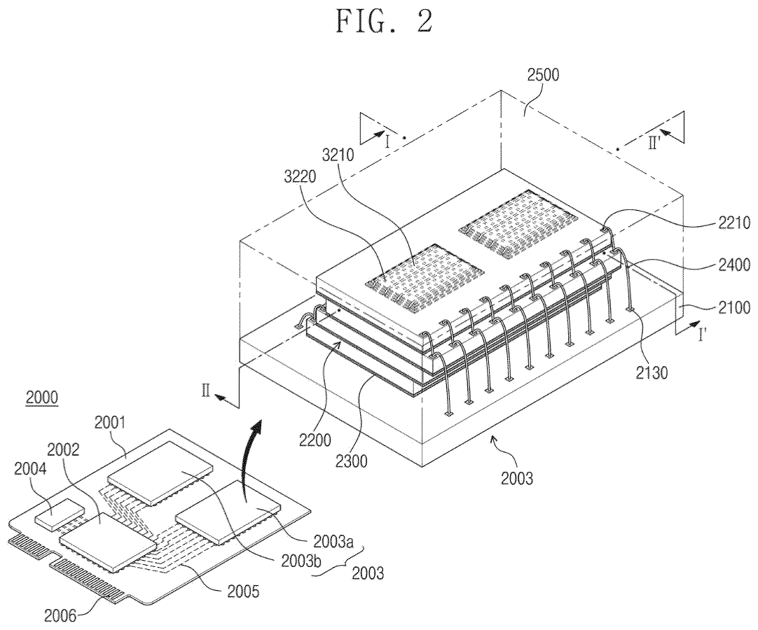

FIG. 2 is a perspective view illustrating an electronic system including a 3D semiconductor memory device according to one or more embodiments.

Referring to FIG. 2, an electronic system 2000 may include a main substrate 2001 and a controller 2002, one or more semiconductor packages 2003, and a dynamic random access memory (RAM) (DRAM) 2004, which are mounted on the main substrate 2001. The semiconductor package 2003 and the DRAM 2004 may be connected to the controller 2002 and to each other by interconnection patterns 2005, which are provided in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and an external host. For example, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In one or more embodiments, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003 and an external host. In one or more embodiments, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed in bottom surfaces of the semiconductor chips 2200, connection structures 2400, which are used to electrically connect the semiconductor chips 2200 to the package substrate 2100, and a molding layer 2500, which is provided on the package substrate 2100 to cover the semiconductor chips 2200 and the connection structures 2400.

The package substrate 2100 may be a printed circuit board, which includes package upper pads 2130. Each of the semiconductor chips 2200 may include input/output pads 2210. Each of the input/output pads 2210 may correspond to the input/output pad 1101 of FIGS. 1A and 1B. Each of the semiconductor chips 2200 may include gate stacks 3210 and memory channel structures 3220. Each of the semiconductor chips 2200 may include a 3D semiconductor memory device, as will be described below.

The connection structures 2400 may be, for example, bonding wires, which are used to electrically connect the input/output pads 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. In one or more embodiments, the semiconductor chips 2200 in each of the first and second semiconductor packages 2003a and 2003b may be electrically connected to each other by through silicon vias (TSVs), not by the connection structure 2400 provided in the form of bonding wires.

The controller 2002 and the semiconductor chips 2200 may be included in a single package. In one or more embodiments, the controller 2002 and the semiconductor chips 2200 may be mounted on a separate interposer substrate, not on the main substrate 2001, and may be connected to each other through interconnection lines, which are provided in the interposer substrate.

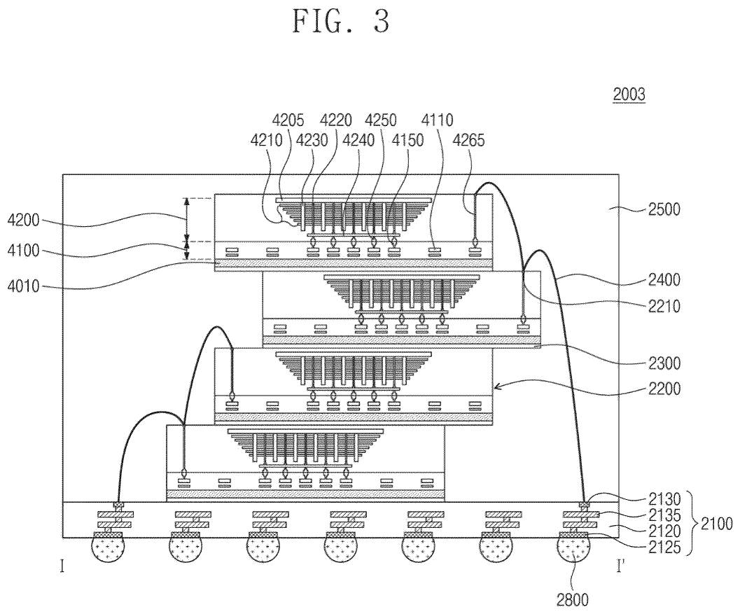

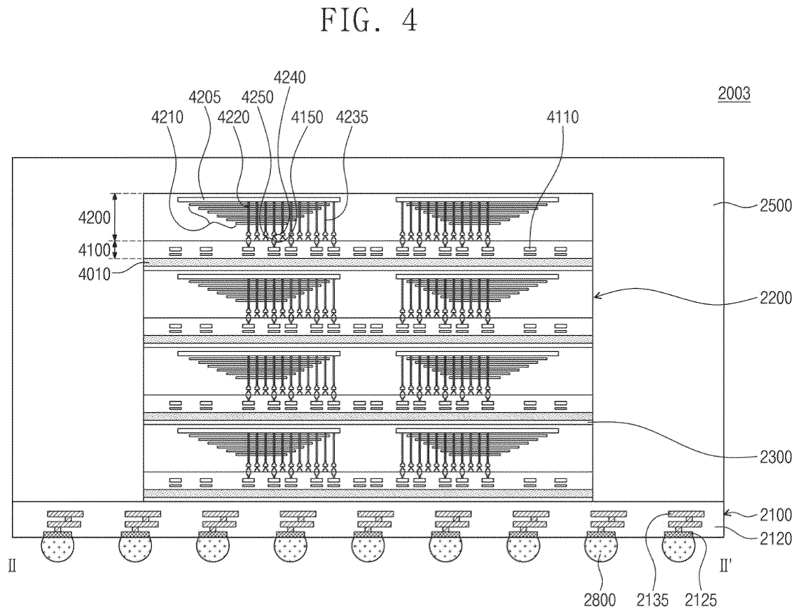

FIG. 3 is a cross-sectional view taken along a line I-I′ of FIG. 2, illustrating a semiconductor package including a semiconductor device according to one or more embodiments. FIG. 4 is a cross-sectional view taken along a line II-II' of FIG. 2, illustrating a semiconductor package including a semiconductor device according to one or more embodiments.

Referring to FIGS. 3 and 4, the semiconductor package 2003 may include the package substrate 2100, the semiconductor chips 2200 on the package substrate 2100, and the molding layer 2500 covering the package substrate 2100 and the semiconductor chips 2200.

The package substrate 2100 may include a package substrate body portion 2120, upper pads 2130, which are provided on a top surface of the package substrate body portion 2120 and are exposed to the outside of the package substrate body portion 2120 near the top surface, lower pads 2125, which are provided on a bottom surface of the package substrate body portion 2120 or are exposed to the outside of the package substrate body portion 2120 near the bottom surface, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000, which is shown in FIG. 2, through conductive connecting portions 2800.

Referring to FIG. 3, the semiconductor chips 2200 may be provided to have side surfaces, which are not aligned to each other, and other side surfaces, which are aligned to each other. The semiconductor chips 2200 may be electrically connected to each other through the connection structures 2400, which are provided in the form of bonding wires. Each of the semiconductor chips 2200 may include substantially the same elements.

Referring back to FIGS. 3 and 4, each of the semiconductor chips 2200 may include a semiconductor substrate 4010, a first structure 4100 on the semiconductor substrate 4010, and a second structure 4200 on the first structure 4100. The second structure 4200 may be bonded to the first structure 4100 in a wafer bonding manner.

The first structure 4100 may include peripheral circuit interconnection lines 4110 and first bonding pads 4150. The second structure 4200 may include a common source line 4205, a gate stack 4210, which is provided between the common source line 4205 and the first structure 4100, memory channel structures 4220 and separation structures 4230, which are provided to penetrate the gate stack 4210, and second bonding pads 4250, which are respectively connected to the memory channel structures 4220 and the word lines WL (e.g., see FIG. 1B) of the gate stack 4210. The back-gate electrode BG of FIG. 1B may be provided in the memory channel structures 4220. For example, the second bonding pads 4250 may be electrically and respectively connected to the memory channel structures 4220 and the word lines WL through bit lines 4240, which are electrically connected to the memory channel structures 4220, and gate connection lines 4235, which are electrically connected to the word lines WL. The first bonding pads 4150 of the first structure 4100 and the second bonding pads 4250 of the second structure 4200 may contact each other and may be bonded to each other. The bonded portions of the first and second bonding pads 4150 and 4250 may be formed of or include, for example, copper (Cu).

Each of the semiconductor chips 2200 may further include an input/output pad 2210 and an input/output connection line 4265 below the input/output pad 2210. The input/output connection line 4265 may be electrically connected to at least one of the second bonding pads 4250 and at least one of the peripheral circuit interconnection lines 4110.

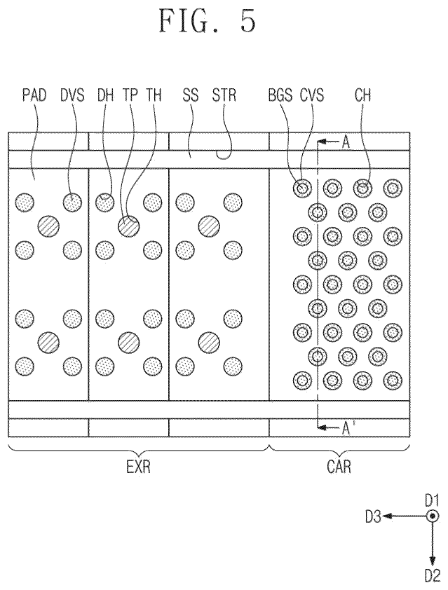

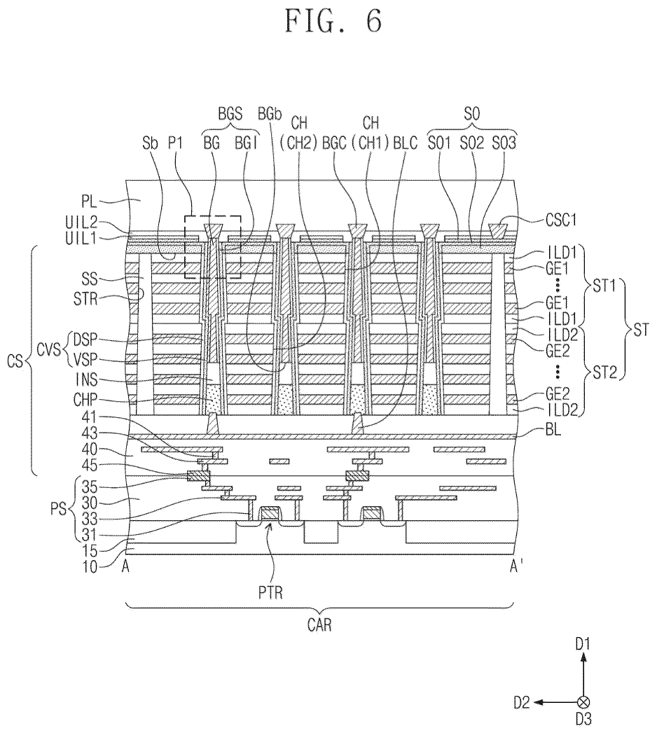

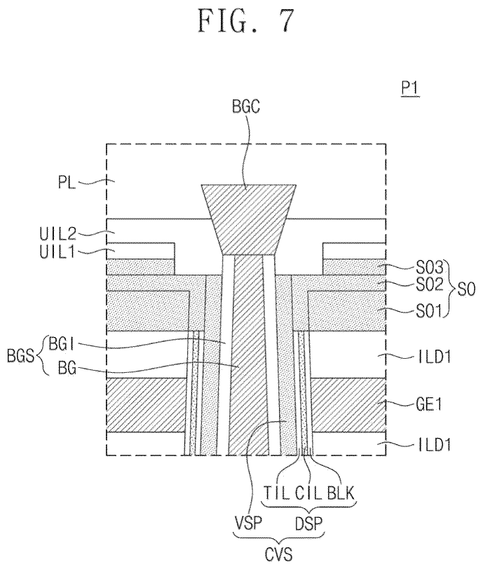

FIG. 5 is a plan view illustrating a 3D semiconductor memory device according to one or more embodiments. FIG. 6 is a cross-sectional view taken along a line A-A′ of FIG. 5 according to one or more embodiments. FIG. 7 is an enlarged view illustrating a portion ‘P1’ of FIG. 6 according to one or more embodiments.

Referring to FIGS. 5 and 6, a 3D semiconductor memory device may include a peripheral circuit structure PS and a cell array structure CS, which are sequentially stacked on a substrate 10. The substrate 10 may correspond to the semiconductor substrate 4010 of FIG. 3 or 4. The peripheral circuit structure PS may correspond to the first structure 4100 of FIG. 3 or 4. The cell array structure CS may correspond to the second structure 4200 of FIG. 3 or 4.

In one or more embodiments, since the cell array structure CS is placed on the peripheral circuit structure PS, the 3D semiconductor memory device may have an increased cell capacity per unit area. The peripheral circuit structure PS and the cell array structure CS may be respectively fabricated, and then, they may be bonded to each other by an additional process. Thus, peripheral transistors PTR, which will be described below, may be prevented from being damaged by various thermal treatment processes. Thus, the electrical and reliability characteristics of the 3D semiconductor memory device may be improved.

The substrate 10 may be a silicon substrate, a silicon-germanium substrate, a germanium substrate, or a structure including a single-crystalline silicon substrate and a single-crystalline epitaxial layer grown therefrom. A plane corresponding to the top surface of the substrate 10 may be perpendicular to a first direction D1. The plane corresponding to the top surface of the substrate 10 may be parallel to a second direction D2 and a third direction D3, which are not parallel to each other. In one or more embodiments, the first to third directions D1, D2, D3 may be orthogonal to each other. A device isolation layer 15 may be provided in the substrate 10. The device isolation layer 15 may define an active region of the substrate 10.

The peripheral circuit structure PS may include the peripheral transistors PTR and peripheral contact plugs 31, which are provided on the substrate 10, peripheral circuit interconnection lines 33, which are electrically connected to the peripheral transistors PTR through the peripheral contact plugs 31, first bonding pads 35, which are electrically connected to the peripheral circuit interconnection lines 33, and a first insulating layer 30 enclosing them. The peripheral transistors PTR may be provided on the active region of the substrate 10. The peripheral circuit interconnection lines 33 may correspond to the peripheral circuit interconnection lines 4110 of FIG. 3 or 4. The first bonding pads 35 may correspond to the first bonding pads 4150 of FIG. 3 or 4.

In one or more embodiments, referring to FIG. 1B, the peripheral transistors PTR may constitute the decoder circuit 1110, the page buffer 1120, and the logic circuit 1130. The peripheral circuit interconnection lines 33 and the first bonding pads 35 may be electrically connected to the peripheral transistors PTR through the peripheral contact plugs 31. Each of the peripheral transistors PTR may be, for example, an n-type metal-oxide-semiconductor (MOS) (NMOS) transistor or a p-type MOS (PMOS) transistor.

In one or more embodiments, a width of the peripheral contact plug 31 in the second or third direction D2 or D3 may increase as a height in the first direction D1 increases. The peripheral contact plugs 31 and the peripheral circuit interconnection lines 33 may be formed of or include at least one of conductive materials (e.g., metallic materials).

The first insulating layer 30 may have a multi-layered structure including a plurality of insulating layers. In one or more embodiments, the first insulating layer 30 may be formed of or include at least one of silicon oxide, silicon nitride, silicon oxynitride, or low-k dielectric materials. The low-k dielectric material may be defined as a material having a dielectric constant lower than silicon oxide. A top surface of the first insulating layer 30 may be substantially coplanar with top surfaces of the first bonding pads 35.

The cell array structure CS may be provided on the peripheral circuit structure PS. The cell array structure CS may include second bonding pads 45, bit lines BL, and a stack ST. The bit lines BL may correspond to the bit lines 4240 of FIG. 3 or 4. The stack ST may correspond to the gate stack 4210 of FIG. 3 or 4. The second bonding pads 45 may correspond to the second bonding pads 4250 of FIG. 3 or 4.

The cell array structure CS may include a cell array region CAR and a cell array extension region EXR. The cell array extension region EXR may be extended from the cell array region CAR in the second direction D2, the third direction D3, or an opposite direction thereof.

The second bonding pads 45 may contact the first bonding pads 35 of the peripheral circuit structure PS. Cell circuit interconnection lines 43 may be electrically connected to the second bonding pads 45 through cell contact plugs 41. A second insulating layer 40 may enclose the bit lines BL, the cell contact plugs 41, the cell circuit interconnection lines 43, and the second bonding pads 45. The second insulating layer 40, the cell contact plugs 41, the cell circuit interconnection lines 43, and the second bonding pads 45 may be provided on the first insulating layer 30.

The second insulating layer 40 may have a multi-layered structure including a plurality of insulating layers. For example, the second insulating layer 40 may be formed of or include at least one of silicon oxide, silicon nitride, silicon oxynitride, or low-k dielectric materials.

In one or more embodiments, a width of the cell contact plug 41 in the second or third direction D2 or D3 may decrease as a height in the first direction D1 increases. The cell contact plugs 41 and the cell circuit interconnection lines 43 may be formed of or include at least one of conductive materials (e.g., metallic materials).

The bit lines BL may extend in the second direction D2 and may be spaced apart from each other in the third direction D3, but embodiments are not limited thereto. The bit lines BL may be formed of or include at least one of conductive materials (e.g., metallic materials).

The bit line BL may be electrically connected to a vertical semiconductor pattern VSP of a cell vertical structure CVS to be described below. In one or more embodiments, a bit line contact BLC may be provided between a channel pad CHP, which may be provided in the cell vertical structure CVS, and the bit line BL, and thus, the bit line BL may be electrically connected to the vertical semiconductor pattern VSP. However, embodiments are not limited thereto. For example, the bit line BL may directly contact at least one of the vertical semiconductor pattern VSP and the channel pad CHP, and in this case, the bit line BL may be electrically connected to the vertical semiconductor pattern VSP.

The bit line contact BLC may be formed of or include at least one of conductive materials (e.g., metallic materials). A width of the bit line contact BLC in the second or third direction D2 or D3 may decrease along the first direction D1.

A bottom surface of the second insulating layer 40 may be substantially coplanar with bottom surfaces of the second bonding pads 45. The first and second bonding pads 35 and 45 may be formed of or include at least one of metallic materials (e.g., copper (Cu), tungsten (W), aluminum (Al), nickel (Ni), or tin (Sn)). In one or more embodiments, the first and second bonding pads 35 and 45 may be formed of or include copper (Cu). The first and second bonding pads 35 and 45 may be connected to each other, without an interface therebetween, to form a single object.

The stack ST and a third insulating layer may be provided on the second insulating layer 40. The third insulating layer may enclose the stack ST. The third insulating layer may have a multi-layered structure including a plurality of insulating layers. The third insulating layer may be formed of or include at least one of silicon oxide, silicon nitride, silicon oxynitride, or low-k dielectric materials. For example, the third insulating layer may be formed of or include high density plasma (HDP) oxide or tetraethyl orthosilicate (TEOS).

In one or more embodiments, a plurality of stacks ST may be provided. In a plan view, the stacks ST may be spaced apart from each other in the second direction D2 and may extend in the third direction D3. Hereinafter, just one stack ST will be described, but the others of the stacks ST may also have substantially the same features as described below.

The stack ST may include a first stack ST1 and a second stack ST2. The first stack ST1 may include first interlayer insulating layers ILD1 and first gate electrodes GE1, which are alternately stacked, and the second stack ST2 may include second interlayer insulating layers ILD2 and second gate electrodes GE2, which are alternately stacked.

The first stack ST1 may be provided on the peripheral circuit structure PS, and the second stack ST2 may be provided between the first stack ST1 and the peripheral circuit structure PS. More specifically, the second stack ST2 may be provided on a bottom surface of the lowermost interlayer insulating layer of the first interlayer insulating layers ILD1 of the first stack ST1. The uppermost interlayer insulating layer of the second interlayer insulating layers ILD2 of the second stack ST2 may contact the lowermost interlayer insulating layer of the first interlayer insulating layers ILD1 of the first stack ST1, but embodiments are not limited thereto. For example, a single interlayer insulating layer may be provided between the uppermost gate electrode of the second gate electrodes GE2 of the second stack ST2 and the first gate electrodes GE1 of the first stack ST1.

In one or more embodiments, the first and second gate electrodes GE1 and GE2 may be formed of or include at least one of doped semiconductor materials (e.g., doped silicon), metallic materials (e.g., tungsten, copper, and aluminum), conductive metal nitride materials (e.g., titanium nitride and tantalum nitride), or transition metal materials (e.g., titanium and tantalum). In one or more embodiments, the first and second interlayer insulating layers ILD1 and ILD2 may be formed of or include at least one of silicon oxide, silicon nitride, silicon oxynitride, or low-k dielectric materials.

In a cross-sectional view, the stack ST may be provided on the cell array extension region EXR to have a staircase structure in the third direction D3. For example, a thickness of the stack ST, which is measured in the first direction D1 on the cell array extension region EXR, may decrease as a distance from the cell array region CAR increases. In one or more embodiments, lengths of the first and second gate electrodes GE1 and GE2 in the third direction D3 may increase as a height from the substrate 10 increases. Each of the first and second gate electrodes GE1 and GE2 may include a pad portion PAD, which is an end portion in the third direction D3. The pad portion PAD may be a region of each of the first and second gate electrodes GE1 and GE2 constituting the staircase portion of the stack ST.

A penetration plug TP may be provided to penetrate the third insulating layer and may extend in the first direction D1. The penetration plug TP may be electrically connected to the pad portion PAD and may be electrically connected to the corresponding gate electrode GE1 or GE2 through the pad portion PAD. The penetration plug TP may be formed of or include at least one of conductive materials (e.g., metallic materials).

At least one of the first gate electrodes GE1 may be used as a ground selection line. The ground selection line may control a ground selection transistor of the first transistors LT1 and LT2 described with reference to FIG. 1B. In one or more embodiments, the ground selection line may be placed in an upper portion of the stack ST.

At least one of the second gate electrodes GE2 may be used as a string selection line. The string selection line may control the string selection transistor of the second transistors UT1 and UT2 described with reference to FIG. 1B. In one or more embodiments, the string selection line may be placed in a lower portion of the stack ST. At least one of the lowermost and second lowest gate electrodes of the second gate electrodes GE2 may be used as the string selection line, but embodiments are not limited thereto.

A separation trench STR may extend in the third direction D3. The separation trench STR may separate the stacks ST from each other in the second direction D2. The separation trench STR may be extended from the cell array region CAR toward the cell array extension region EXR. A width of the separation trench STR in the second direction D2 may decrease as a height in the first direction D1 increases.

A separation pattern SS may be provided to fill an inner space of the separation trench STR. The separation pattern SS may correspond to the separation structures 4230 of FIG. 3 or 4. Each of top and bottom surfaces of the separation pattern SS may be placed at a level that is substantially equal or different from that of each of top and bottom surfaces of the stack ST. In one or more embodiments, the separation patterns SS may be formed of or include at least one of silicon oxide, silicon nitride, silicon oxynitride, or low-k dielectric materials.

Channel holes CH may be provided to penetrate the cell array structure CS in the cell array region CAR and the cell array extension region EXR. Each of the channel holes CH may be provided to penetrate at least one of the stack ST and the third insulating layer in the first direction D1. In one or more embodiments, each of the channel holes CH may include a first channel hole CH1 penetrating the first stack ST1 and a second channel hole CH2 penetrating the second stack ST2. A width of each of the first and second channel holes CH1 and CH2 in at least one of the second and third directions D2 and D3 may decrease as a height in the first direction D1 increases. The first and second channel holes CH1 and CH2 may be connected to each other. At a boundary between the first and second channel holes CH1 and CH2, a diameter of the second channel hole CH2 may be smaller than a diameter of the first channel hole CH1. The first and second channel holes CHI and CH2 may form a staircase structure near the boundary region. However, embodiments are not limited thereto, and in one or more embodiments, three or more channel holes may be provided to form the staircase structures near two or more boundaries, unlike that illustrated in the drawings. Alternatively, the channel holes may be provided to have a flat side surface without a staircase portion, unlike that illustrated in the drawings.

In the cell array region CAR, the cell vertical structures CVS may be provided to penetrate the stack ST in the first direction D1 and to conformally cover the channel hole CH. The cell vertical structures CVS may correspond to the memory channel structures 4220 of FIG. 3 or 4.

In one or more embodiments, the channel pad CHP may be provided below the cell vertical structure CVS. The channel pad CHP may be located at a level that is lower than a bottom surface Sb of a source layer SO to be described below. The channel pad CHP may be provided in the cell vertical structure CVS and may be enclosed by a lower portion of the cell vertical structure CVS. In one or more embodiments, the channel pad CHP may be formed of or include at least one of doped semiconductor materials or conductive materials. The bit line contacts BLC may contact bottom surfaces of the channel pads CHP. Thus, the cell vertical structures CVS may be electrically connected to the bit lines BL through the channel pads CHP and the bit line contacts BLC.

In the cell array extension region EXR, dummy vertical structures DVS may be provided to penetrate at least one of the stack ST and the third insulating layer in the first direction D1 and to fill the channel holes CH, respectively. For example, each of bottom surfaces of the cell and dummy vertical structures CVS and DVS may have a circular, elliptical, or bar shape.

Each of the cell vertical structures CVS may include a data storage pattern DSP and the vertical semiconductor pattern VSP, which are provided to sequentially and conformally cover an inner surface of the channel hole CH. The vertical semiconductor pattern VSP may be provided between the data storage pattern DSP and a back-gate electrode BG to be described below. The vertical semiconductor pattern VSP may be formed of or include at least one of doped semiconductor materials, undoped or intrinsic semiconductor materials, or polycrystalline semiconductor materials.

The vertical semiconductor pattern VSP may contact the channel pad CHP. Accordingly, the vertical semiconductor pattern VSP may be electrically connected to the bit line BL through the channel pad CHP and the bit line contact BLC. In one or more embodiments, the vertical semiconductor pattern VSP may contact the channel pad CHP with an interface therebetween, but embodiments are not limited thereto. In another embodiment, the vertical semiconductor pattern VSP and the channel pad CHP may form a single object without any observable interface therebetween.

Referring to FIG. 7, the data storage pattern DSP may include a blocking insulating layer BLK, a charge storing layer CIL, and a tunneling insulating layer TIL, which are sequentially stacked on an inner side surface of the channel hole CH. The charge storing layer CIL may be interposed between the blocking insulating layer BLK and the tunneling insulating layer TIL. The blocking insulating layer BLK, the charge storing layer CIL, and the tunneling insulating layer TIL may be extended along the inner side surface of the channel hole CH, between the stack ST and the vertical semiconductor pattern VSP.

In one or more embodiments, the Fowler-Nordheim (FN) tunneling phenomenon, which is caused by a voltage difference between the vertical semiconductor pattern VSP and the first and second gate electrodes GE1 and GE2, may be used to store or change data in the data storage pattern DSP. In one or more embodiments, the blocking insulating layer BLK and the tunneling insulating layer TIL may be formed of or include silicon oxide, and the charge storing layer CIL may be formed of or include at least one of silicon nitride or silicon oxynitride.

Referring back to FIGS. 5 and 6, a back-gate structure BGS may be provided in the cell vertical structure CVS and may extend in the first direction D1. The back-gate structure BGS may be enclosed by the cell vertical structure CVS. The back-gate structure BGS may be provided on a top surface of the channel pad CHP. The back-gate structure BGS may be vertically overlapped with the channel pad CHP. In one or more embodiments, a plurality of back-gate structures BGS may be provided. Each of the back-gate structures BGS may be provided in a corresponding one of the cell vertical structures CVS.

The back-gate structure BGS may include a back-gate insulating layer BGI and the back-gate electrode BG, which are sequentially provided on a side surface of the vertical semiconductor pattern VSP of the cell vertical structure CVS. The back-gate insulating layer BGI may include an insulating material, and the back-gate electrode BG may include a conductive material. In one or more embodiments, the back-gate electrode BG may be formed of or include at least one of metallic materials or doped polysilicon. Although not shown, the back-gate electrode BG may include a pillar-shaped insulating pattern, which is provided in the back-gate electrode BG. The back-gate electrode BG may correspond to the back-gate electrode BG described with reference to FIG. 1B. The back-gate electrode BG may correspond to the back-gate electrode BG, which is provided in the memory channel structure 4220 described with reference to FIG. 3 or 4.

In the cell vertical structure CVS, the back-gate electrode BG may extend in the first direction D1. The back-gate insulating layer BGI may be provided to enclose a side surface of the back-gate electrode BG. Thus, the back-gate electrode BG may be spaced apart from, and electrically disconnected from, the vertical semiconductor pattern VSP of the cell vertical structure CVS.

Each of the back-gate electrodes BG may be horizontally adjacent to a plurality of gate electrodes GE1, GE2 in the stack ST. The back-gate electrode BG may not be adjacent to the second gate electrodes GE2, which are not used as the string selection line, in a horizontal direction. For example, a bottom surface BGb of the back-gate electrode BG may be located at a level that is higher than a top surface of one of the second gate electrodes GE2 serving as the string selection line.

A top surface of the back-gate electrode BG may be located at a level higher than the top surface of the stack ST. The top surface of the back-gate electrode BG may be located at a level higher than the bottom surface Sb of the source layer SO. In one or more embodiments, the top surface of the back-gate electrode BG may be located at a level that is substantially equal to or lower than a top surface of the source layer SO.

In one or more embodiments, the back-gate electrode BG may include an upper portion and a lower portion, which are connected to each other to form a staircase structure. A width of each of the upper and lower portions of the back-gate electrode BG in the second or third direction D2 or D3 may decrease as a height in the first direction D1 increases.

An internal insulating pattern INS may be interposed between the back-gate electrode BG and the channel pad CHP. The internal insulating pattern INS may include an insulating material. The back-gate electrode BG may be spaced apart from and electrically disconnected from the channel pad CHP by the internal insulating pattern INS.

The source layer SO may be provided on the cell array structure CS to cover the top surface of the stack ST. In one or more embodiments, the source layer SO may contact the top surface of the stack ST. The source layer SO may contact and electrically connected to the vertical semiconductor pattern VSP of the cell vertical structure CVS. Alternatively, the source layer SO may be spaced apart from and electrically disconnected from the back-gate electrode BG of the back-gate structure BGS. The source layer SO may extend in the second and third direction D2 and D3. The source layer SO may correspond to the common source line 4205 of FIG. 3 or 4.

The source layer SO may include a first source layer SO1, a second source layer SO2, and a third source layer SO3, which are stacked in the first direction D1. At least one of the first to third source layers SO1, SO2, and SO3 may include a conductive material. In one or more embodiments, the first and third source layers SO1 and SO3 may be formed of or include doped polysilicon, and the second source layer SO2 may be formed of or include undoped polysilicon. The first source layer SO1 may contain impurities of a first conductivity type (e.g., n-type impurities). In one or more embodiments, the third source layer SO3 may contain impurities of a second conductivity type (e.g., p-type impurities). FIG. 6 illustrates an example in which the first to third source layers SO1, SO2, and SO3 contact each other with an interface therebetween, but embodiments are not limited thereto.

At least one (e.g., the second source layer SO2) of the first to third source layers SO1, SO2, and SO3 may contact the vertical semiconductor pattern VSP. Thus, the first to third source layers SO1, SO2, and SO3 may be electrically connected to the channel pad CHP, the bit line contact BLC, and the bit line BL through the vertical semiconductor pattern VSP.

A first upper insulating layer UIL1 and a second upper insulating layer UIL2 may cover the top surface of the source layer SO. The first upper insulating layer UIL1 may cover a top surface of the third source layer SO3, and the second upper insulating layer UIL2 may cover a top surface of the first upper insulating layer UIL1. A portion of the second upper insulating layer UIL2 may be interposed between the third source layer SO3 and the back-gate structure BGS. The first and second upper insulating layers UIL1 and UIL2 may be formed of or include an insulating material. In one or more embodiments, the first and second upper insulating layers UIL1 and UIL2 may be connected to each other, without an interface therebetween, to form a single object. The first to third source layers SO1, SO2, and SO3 may be spaced apart from and electrically disconnected from the back-gate electrode BG by the back-gate insulating layer BGI and the second upper insulating layer UIL2.

A back-gate contact BGC may be provided on the top surface of the back-gate electrode BG. The back-gate contact BGC may penetrate the second upper insulating layer UIL2 and may contact the top surface of the back-gate electrode BG. The back-gate contact BGC may be formed of or include at least one of conductive materials (e.g., metallic materials). The back-gate contact BGC may be spaced apart from and electrically disconnected from each of the source layer SO and the cell vertical structure CVS by the second upper insulating layer UIL2. A width of the back-gate contact BGC in the second or third direction D2 or D3 may increase in the first direction D1.

A first source contact CSC1 may contact the top surface of the third source layer SO3. A second source contact may contact a top surface of the first source layer SO1. Each of the first source contact CSC1 and the second source contact may be formed of or include at least one of conductive materials (e.g., metallic materials).

A protection layer PL may be provided on the cell array structure CS. The protection layer PL may be a single layer, which is made of a single material, or a composite layer including two or more materials. In one or more embodiments, the protection layer PL may have a structure, in which silicon oxide, silicon nitride, and polyimide-based materials (e.g., photo-sensitive polyimide (PSPI)) are sequentially stacked, but embodiments are not limited thereto. The protection layer PL may have an opening, which is formed to expose some of input/output pads. Upper interconnection lines may be provided in the protection layer PL and may be electrically connected to the cell array structure CS and the source layer SO.

In one or more embodiments, the back-gate contact BGC may be an additional contact, which is provided between the back-gate electrode BG of FIG. 1B and the back-gate line BGL of FIG. 1B and is used to electrically connect them to each other, but embodiments are not limited thereto. In this case, at least one of the upper interconnection lines in the protection layer PL may correspond to the back-gate line BGL.

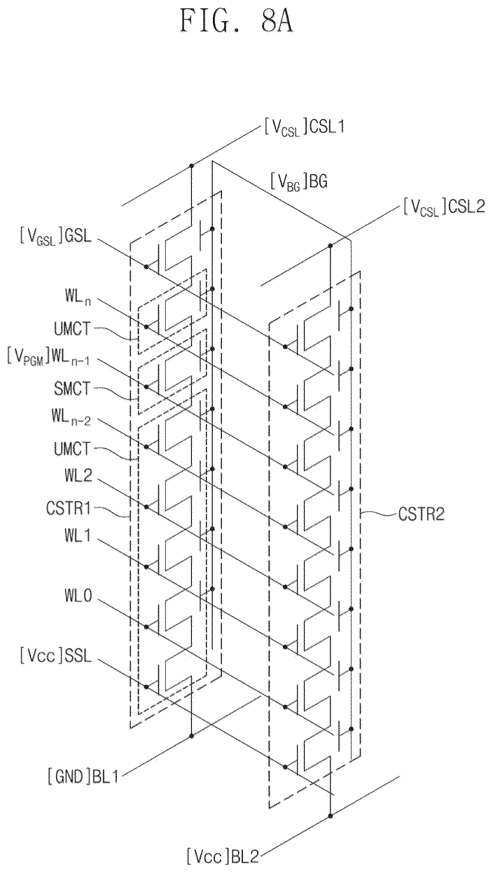

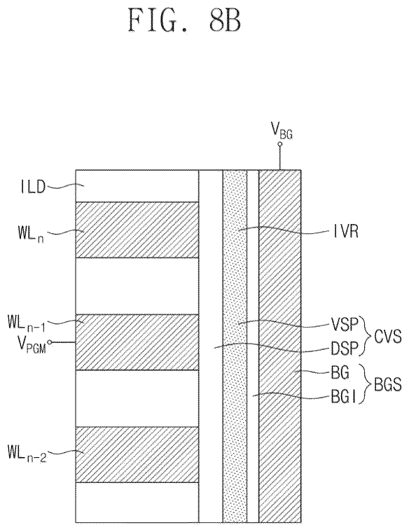

FIG. 8A is a diagram illustrating a voltage condition for a programming operation on a 3D semiconductor memory device, according to one or more embodiments. FIG. 8B is a diagram illustrating a programming operation on a 3D semiconductor memory device, according to one or more embodiments.

Referring to FIGS. 8A and 8B, during a programming operation, a first cell string CSTR1 may be selected, and a second cell string CSTR2 may not be selected. The first cell string CSTR1 may include one selected memory cell SMCT. The second cell string CSTR2 may not include the selected memory cell.

The first and second cell strings CSTR1 and CSTR2 may share one string selection line SSL. The first and second cell strings CSTR1 and CSTR2 may share one selected word line WLₙ₋₁ and unselected word lines WL0, WL1, WL2, WLₙ₋₂, and WLₙ. The first and second cell strings CSTR1 and CSTR2 may share one ground selection line GSL. Each of the first and second cell strings CSTR1 and CSTR2 may be connected to the back-gate electrode BG. The first cell string CSTR1 may be connected to a first bit line BL1, and the second cell string CSTR2 may be connected to a second bit line BL2. The first cell string CSTR1 may be connected to a first common source line CSL1, and the second cell string CSTR2 may be connected to a second common source line CSL2.

The string selection transistor of the first cell string CSTR1 may be turned on, and the string selection transistor of the second cell string CSTR2 may be turned off. That is, a difference between voltages, which are respectively applied to the string selection line SSL and the first bit line BL1, may be greater than a threshold voltage of the string selection transistor. Alternatively, a difference between voltages, which are respectively applied to the string selection line SSL and the second bit line BL2, may be smaller than the threshold voltage of the string selection transistor. In one or more embodiments, a power voltage Vcc may be applied to the string selection line SSL, a ground voltage GND may be applied to the first bit line BL1, and a power voltage Vcc may be applied to the second bit line BL2.

In addition, a program voltage V_{PGM} may be applied to the selected word line WLₙ₋₁. Each of the unselected word lines WL0, WL1, WL2, WLₙ₋₂, and WLₙ, may be in an electrically floated state. A back-gate voltage V_{BG} may be applied to the back-gate electrode BG.

The ground selection transistors of the first and second cell strings CSTR1 and CSTR2 may be turned off. That is, a difference between a common source voltage V_{CSL} and a ground selection voltage V_{GSL}, which are respectively applied to the first common source line CSL1 and the ground selection line GSL, may be smaller than a threshold voltage of the ground selection transistor. Similarly, a difference between the common source voltage V_{CSL}, which is applied to the second common source line CSL2, and the ground selection voltage V_{GSL} may be smaller than the threshold voltage of the ground selection transistor.

In one or more embodiments, if a programming operation is performed under the voltage condition, an inversion region IVR may be formed in the vertical semiconductor pattern VSP by applying the back-gate voltage V_{BG} to the back-gate electrode BG, even when the unselected word lines WL0, WL1, WL2, WLₙ₋₂, and WLₙ, are in an electrically floated state. Thus, the ground voltage GND, which is applied to the first bit line BL1, may be delivered to the inversion region IVR in the vertical semiconductor pattern VSP. In this case, due to a difference between the program voltage V_{PGM}, which is applied to the selected word line WLₙ₋₁, and the ground voltage GND of the vertical semiconductor pattern VSP in the first cell string CSTR1, data may be written in the selected memory cell SMCT.

In one or more embodiments, to form the inversion region IVR in the vertical semiconductor pattern VSP of the first cell string CSTR1, it may be unnecessary to apply an additional voltage to the unselected word lines WL0, WL1, WL2, WLₙ₋₂, and WLₙ. Thus, undesired data may be prevented from being written in unselected memory cells UMCT by the additional voltage applied to the unselected word lines WL0, WL1, WL2, WLₙ₋₂, and WLₙ. That is, a disturbance issue in the programming operation of the 3D semiconductor memory device may be reduced and the reliability of the 3D semiconductor memory device may be improved.

If the programming operation is performed under the voltage condition, an inversion region may be formed in a vertical semiconductor pattern in the second cell string CSTR2 by the back-gate voltage V_{BG} applied to the back-gate electrode BG. Since both the string and ground selection transistors of the second cell string CSTR2 are turned off, a voltage of the inversion region may be boosted by the back-gate voltage V_{BG}. A difference between the program voltage V_{PGM}, which is applied to the selected word line WLₙ₋₁, and the voltage of the inversion region, which is boosted by the back-gate voltage V_{BG}, may be smaller than a voltage required to write data in a memory cell. Thus, undesired data may be prevented from being written in the memory cell of the second cell string CSTR2 sharing the selected word line WLₙ₋₁. That is, a disturbance issue in the programming operation of the 3D semiconductor memory device may be reduced and the reliability of the 3D semiconductor memory device may be improved.

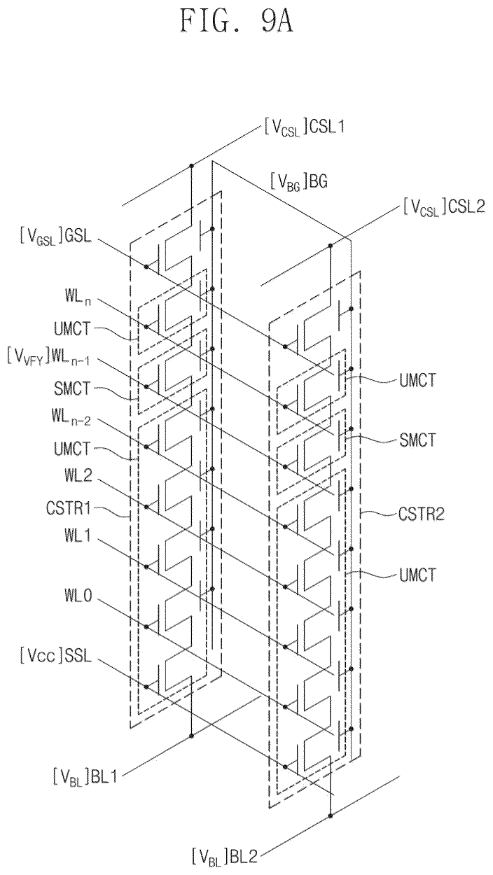

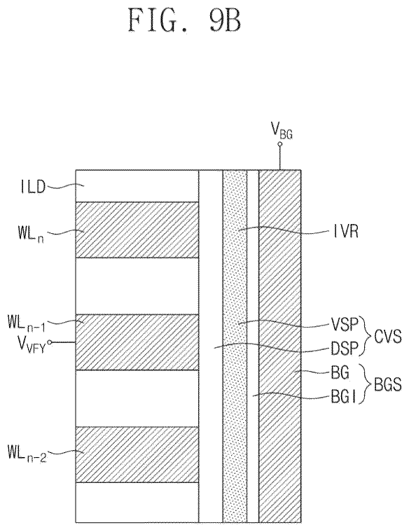

FIG. 9A is a diagram illustrating a voltage condition for a reading operation on a 3D semiconductor memory device according to one or more embodiments. FIG. 9B is a diagram illustrating a reading operation on a 3D semiconductor memory device according to one or more embodiments.

Referring to FIGS. 9A and 9B, both of the first and second cell strings CSTR1 and CSTR2 may be selected, during the reading operation. Each of the first and second cell strings CSTR1 and CSTR2 may include one selected memory cell SMCT.

A string selection transistor of each of the first and second cell strings CSTR1 and CSTR2 may be turned on. In one or more embodiments, a string selection voltage VSSL may be applied to the string selection line SSL, and a bit line voltage VBL may be applied to each of the first and second bit lines BLI and BL2. A difference between the string selection voltage VSSL and the bit line voltage VBL may be greater than the threshold voltage of the string selection transistor.

In addition, a verify voltage V_{VFY} may be applied to the selected word line WLₙ₋₁. Each of the unselected word lines WL0, WL1, WL2, WLₙ₋₂, and WLₙ, may be in an electrically floated state. The back-gate voltage V_{BG} may be applied to the back-gate electrode BG.

Each of ground selection transistors of the first and second cell strings CSTR1 and CSTR2 may be turned on. That is, a difference between the common source voltage V_{CSL} of each of the first and second common source lines CSL1 and CSL2, and the ground selection voltage V_{GSL} may be greater than the threshold voltage of the ground selection transistor.

In the case where a reading operation is performed under the voltage condition, the verify voltage V_{VFY} may be applied to the selected word line WLₙ₋₁, and by measuring a current flowing through the vertical semiconductor pattern VSP, data, which is stored in the selected memory cell SMCT of each of the first and second cell strings CSTR1 and CSTR2, may be read.

In one or more embodiments, the back-gate voltage V_{BG} may be applied to the back-gate electrode BG, and the inversion region IVR for current conduction may be formed in the vertical semiconductor pattern VSP by the back-gate voltage V_{BG}. Thus, to form the inversion region IVR, it may be unnecessary to apply an additional voltage to each of the unselected word lines WL0, WL1, WL2, WLₙ₋₂, and WLₙ. Thus, undesired data may be prevented from being written in unselected memory cells UMCT by the additional voltage applied to the unselected word lines WL0, WL1, WL2, WLₙ₋₂, and WLₙ. That is, a disturbance issue in the reading operation of the 3D semiconductor memory device may be reduced and the reliability of the 3D semiconductor memory device may be improved.

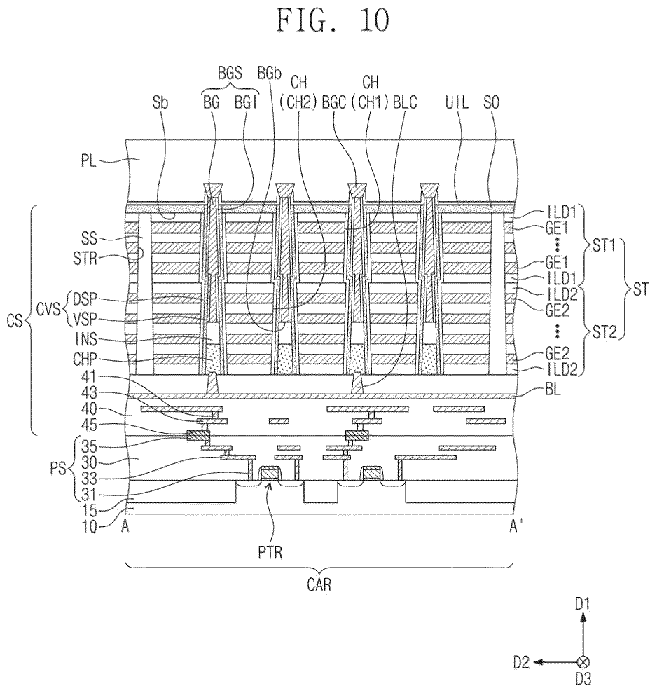

Hereinafter, a 3D semiconductor memory device according to one or more embodiments will be described in more detail with reference to FIG. 10. In the following description, a previously-described element may be identified by the same reference number without repeating an overlapping description thereof, for concise description. Repeated descriptions of similar elements to those described above may be omitted.

FIG. 10 is a cross-sectional view along a line of a semiconductor memory device that corresponds to the line A-A′ of FIG. 5 according to one or more embodiments.

Referring to FIG. 10, the source layer SO may be provided on the cell array structure CS and may contact the top surface of the stack ST. In one or more embodiments, the source layer SO may include the same material as the first source layer SO1 described with reference to FIGS. 6 and 7. The source layer SO may contact and electrically connected to the vertical semiconductor pattern VSP.

An upper insulating layer UIL may conformally cover the source layer SO and a portion of a side surface of the back-gate structure BGS. The upper insulating layer UIL may include an insulating material.

The data storage pattern DSP of the cell vertical structure CVS may be provided to have substantially the same features as those in the embodiment described with reference to FIGS. 6 and 7.

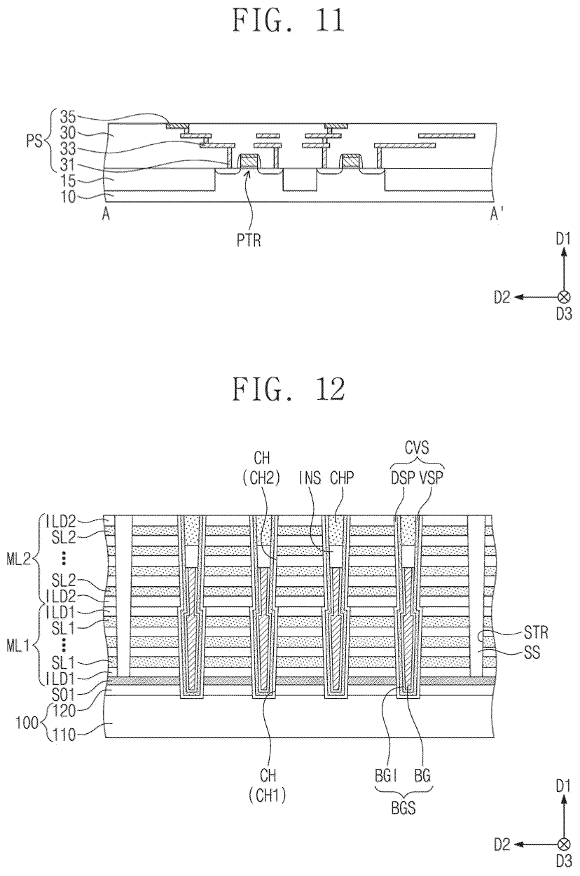

FIGS. 11 to 16 are cross-sectional views illustrating a method of fabricating a 3D semiconductor memory device, according to one or more embodiments FIGS. 11 to 16 are cross-sectional views taken along the line A-A′ of FIG. 5.

Referring to FIGS. 5 and 11, the peripheral circuit structure PS may be formed on the substrate 10. The formation of the peripheral circuit structure PS may include forming the device isolation layer 15 in the substrate 10, forming the peripheral transistors PTR on the active region of the substrate 10 defined by the device isolation layer 15, and forming the peripheral contact plugs 31, the peripheral circuit interconnection lines 33, and the first bonding pads 35, which are electrically connected to the peripheral transistors PTR, and the first insulating layer 30 covering them.

Top surfaces of the first bonding pads 35 may be substantially coplanar with the top surface of the first insulating layer 30. In one or more embodiments, a planarization process may be performed to form the substantially coplanar surfaces.

In the following description of the fabrication method, various devices may have a flipped orientation for the purposes of describing the method, and thus reference to top/bottom surfaces and upper/lower portions may be reversed to correspond to the view depicted in the figures.

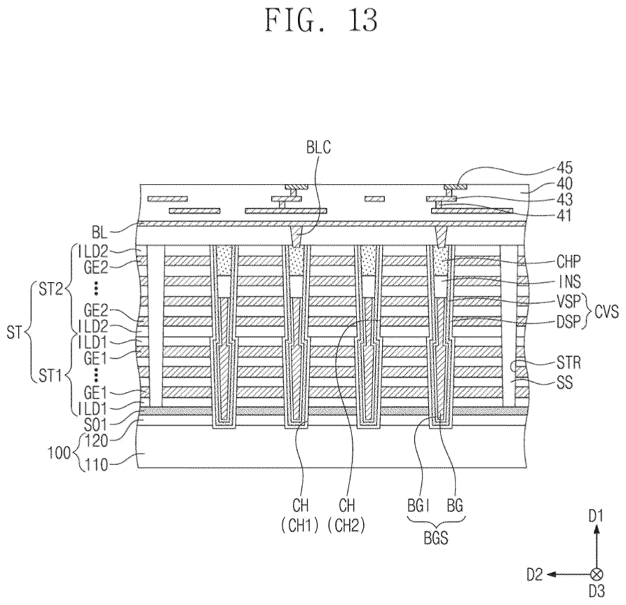

Referring to FIGS. 5 and 12, a cell array substrate 100 may be provided. The cell array substrate 100 may include a first cell array substrate 110 and a second cell array substrate 120 sequentially stacked.

In one or more embodiments, the first cell array substrate 110 may be a silicon substrate, a silicon-germanium substrate, a germanium substrate, or a single-crystalline epitaxial layer grown on a single-crystalline silicon substrate. The second cell array substrate 120 may include a material having an etch selectivity with respect to the first cell array substrate 110. As an example, the second cell array substrate 120 may include an insulating material.

The first source layer SO1 may be formed on the second cell array substrate 120. The first source layer SO1 may have an etch selectivity with respect to the second cell array substrate 120.

A mold structure ML may be formed on the first source layer SO1. The mold structure ML may include a first mold structure ML1 and a second mold structure ML2 on the first mold structure ML1.

The formation of the first mold structure ML1 may include alternately stacking first interlayer insulating layers ILD1 and first sacrificial layers SL1 on the first source layer SO1. In the first mold structure ML1, the first sacrificial layers SL1 may be formed of or include a material, which can be etched with an etch selectivity with respect to the first interlayer insulating layers ILD1. In one or more embodiments, the first sacrificial layers SL1 may be formed of or include an insulating material different from the first interlayer insulating layers ILD1. For example, the first sacrificial layers SL1 may be formed of or include silicon nitride, and the first interlayer insulating layers ILD1 may be formed of or include silicon oxide.

The first channel hole CHI may be formed to penetrate the first interlayer insulating layers ILD1 and the first sacrificial layers SL1 in the first direction D1. In one or more embodiments, the separation trench STR, a dummy hole DH, and a penetration hole TH may be formed together when the first channel hole CH1 is being formed, but embodiments are not limited thereto.

The second mold structure ML2 may be formed on the first mold structure ML1. The formation of the second mold structure ML2 may include alternately stacking the second interlayer insulating layers ILD2 and second sacrificial layers SL2. The second interlayer insulating layers ILD2 and the second sacrificial layers SL2 may have the same or similar features as those in the first interlayer insulating layers ILD1 and the first sacrificial layers SL1.

The second channel hole CH2 may be formed to penetrate the second interlayer insulating layers ILD2 and the second sacrificial layers SL2 in the first direction D1. In one or more embodiments, the separation trench STR, the dummy hole DH, and the penetration hole TH may be formed together when the second channel hole CH2 is being formed, but embodiments are not limited thereto. The first and second channel holes CH1 and CH2 may constitute a channel hole CH.

The cell vertical structure CVS, the dummy vertical structure DVS, and the penetration plug TP may be formed to fill the channel hole CH, the dummy hole DH, and the penetration hole TH, respectively. The formation of the cell vertical structure CVS may include sequentially and conformally forming the data storage pattern DSP and the vertical semiconductor pattern VSP in the channel hole CH.

The back-gate structure BGS may be formed to fill the channel hole CH, on the cell vertical structure CVS. The formation of the back-gate structure BGS may include forming the back-gate insulating layer BGI to conformally cover an inner side surface of the cell vertical structure CVS and a top surface of the second mold structure ML2, forming a back-gate electrode layer to fill a remaining portion of the channel hole CH and to cover a top surface of the second mold structure ML2, and performing a removal process on the back-gate insulating layer BGI and an upper portion of the back-gate electrode layer to form a plurality of back-gate insulating layers BGI, which are separated from each other, and a plurality of back-gate electrodes BG, which are separated from each other.

The internal insulating pattern INS and the channel pad CHP may be formed on the back-gate structure BGS to sequentially fill an upper portion of the channel hole CH. The dummy vertical structure DVS and the cell vertical structure CVS may be formed by the same process or by respective processes.

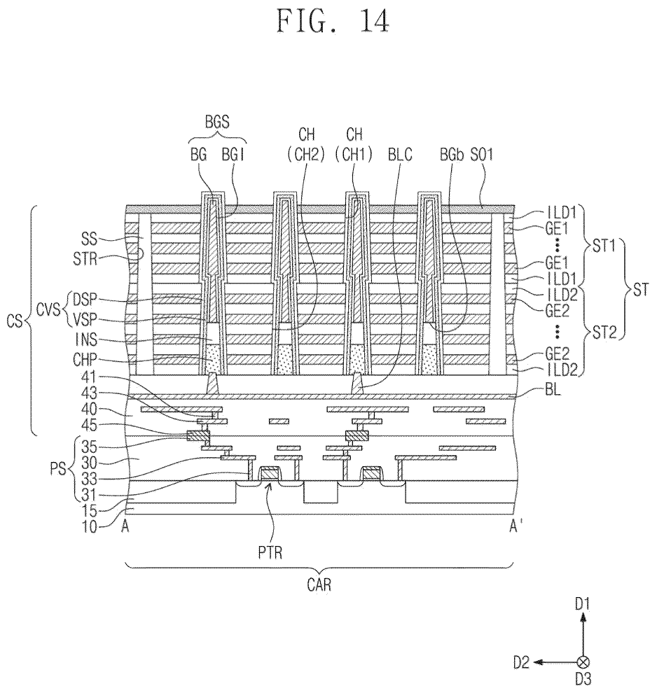

Referring to FIGS. 5 and 13, an isotropic etching process, in which the separation trench STR is used as a supply path, may be performed to remove the first sacrificial layers SL1 and the second sacrificial layers. Thereafter, the first and second gate electrodes GE1 and GE2, which constitute the stack ST, may be formed in empty spaces, which are formed by removing the first sacrificial layers SL1 and the second sacrificial layers. The separation pattern SS may be formed to fill the separation trench STR.

The second insulating layer 40, the bit line contacts BLC, the bit line BL, the cell contact plugs 41, the cell circuit interconnection lines 43, and the second bonding pads 45 may be formed on the stack ST.

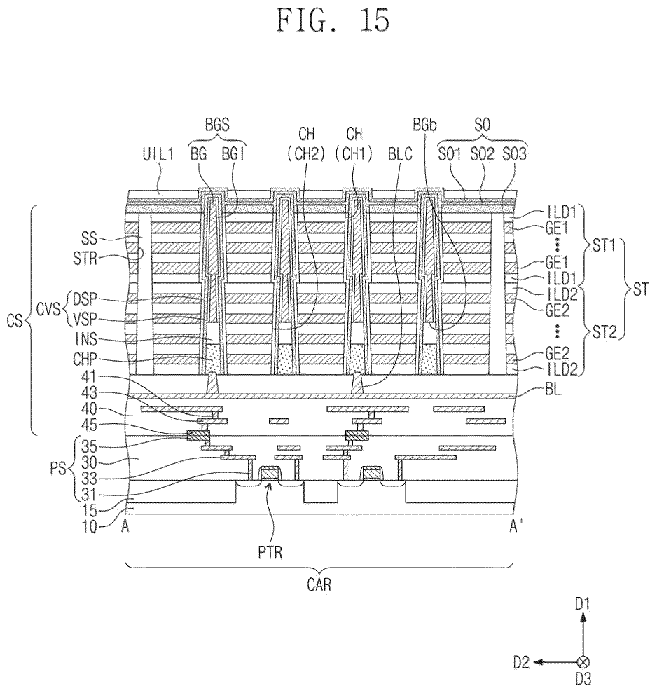

Referring to FIGS. 5 and 14, the peripheral circuit structure PS and the cell array structure CS may be combined to each other. The first bonding pads 35 of the peripheral circuit structure PS and the second bonding pads 45 of the cell array structure CS may be bonded to each other to contact each other.

Since the first and second bonding pads 35 and 45 are bonded to each other, the cell array structure CS may be inverted.

After the bonding process, the first cell array substrate 110 may be removed. The removal of the first cell array substrate 110 may include at least one of a grinding process, a planarization process, a dry etching process, and a wet etching process.

The second cell array substrate 120 may be removed from the cell array region CAR. The first source layer SO1 may be used as an etch stop layer, and during the removal process, the first source layer SO1 may not be removed or may be less removed. During the removal process on the second cell array substrate 120, the data storage pattern DSP of the cell vertical structure CVS may be exposed to the outside.

Referring to FIGS. 5 and 15, the exposed portion of the data storage pattern DSP and a portion of the data storage pattern DSP, which is adjacent to the first source layer SO1 in a horizontal direction, may be removed. Thus, a portion of the vertical semiconductor pattern VSP may be exposed to the outside.

The second source layer SO2 may be formed to conformally cover the top surface of the first source layer SO1 and the exposed portion of the vertical semiconductor pattern VSP. Thereafter, the third source layer SO3 may be formed to conformally cover a top surface of the second source layer SO2. The first to third source layers SO1, SO2, and SO3 may constitute the source layer SO.

The first upper insulating layer UIL1 may be formed to cover the top surface of the third source layer SO3. Thus, a removal process may be performed on an upper portion of the first upper insulating layer UIL1, and thus, the topmost surface of the third source layer SO3 may be exposed to the outside.

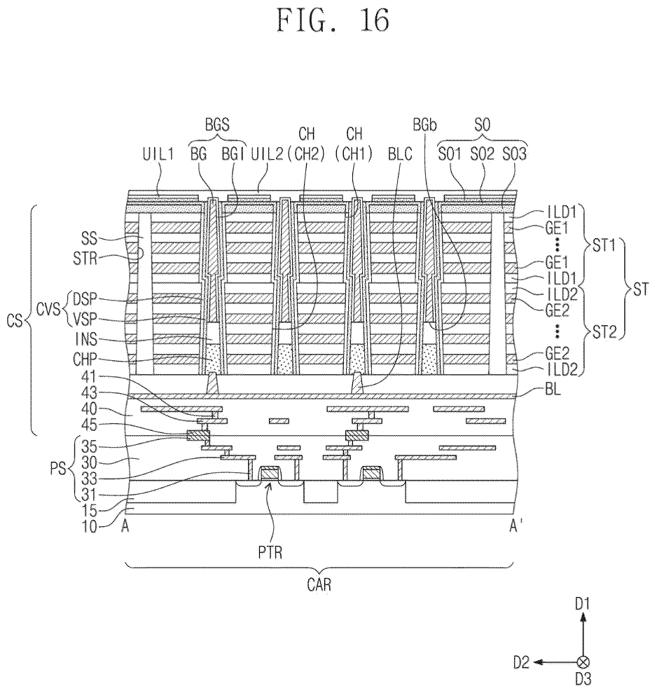

Referring to FIGS. 5 and 16, a removal process may be performed on a portion of the source layer SO and a portion of the first upper insulating layer UIL1. Thus, an upper portion of the back-gate structure BGS may be exposed to the outside.

The second upper insulating layer UIL2 may be formed to cover the exposed upper portion of the back-gate structure BGS. The second upper insulating layer UIL2 may be formed to cover the top surface of the first upper insulating layer UIL1.

Referring back to FIGS. 5 and 6, the back-gate contact BGC may be formed to contact the top surface of the back-gate electrode BG. The first source contact CSC1 may be formed to contact the top surface of the third source layer SO3, and a second source contact may be formed to contact the top surface of the first source layer SO1. The protection layer PL may be formed to cover the cell array structure CS.

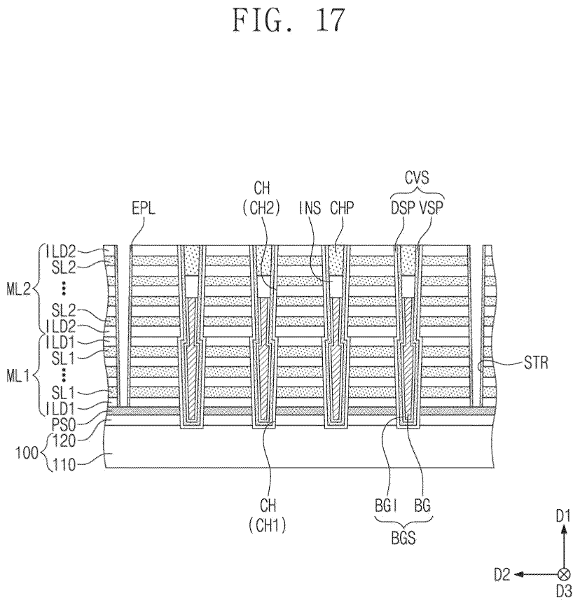

FIGS. 17 to 20 are cross-sectional views illustrating a method of fabricating a 3D semiconductor memory device, according to one or more embodiments. FIGS. 17 to 20 are sectional views taken along the line A-A′ of FIG. 5, although the device fabricated in FIGS. 17-20 may be different from or include different elements from the device fabricated in FIGS. 11-16.

Referring to FIGS. 5 and 17, a preliminary source layer PSO may be provided, instead of the first source layer SO1 described with reference to FIGS. 5 and 12. The preliminary source layer PSO may include a first preliminary source layer, a second preliminary source layer, a third preliminary source layer, a fourth preliminary source layer, and a fifth preliminary source layer, which are sequentially stacked on the second cell array substrate 120. In one or more embodiments, the first and fifth preliminary source layers may be formed of or include doped polysilicon. The second to fourth preliminary source layers may include an insulating material. The second and fourth preliminary source layers may be formed of or include silicon oxide, and the third preliminary source layer may be formed of or include silicon nitride.

In the following description of the fabrication method, various devices may have a flipped orientation for the purposes of describing the method, and thus reference to top/bottom surfaces and upper/lower portions may be reversed to correspond to the view depicted in the figures.

After the formation of the channel pad CHP described with reference to FIGS. 5 and 12, an etch protection layer EPL may be formed to conformally cover inner surfaces of the separation trenches STR. A removal process may be performed on a lower portion of the etch protection layer EPL. A portion of the preliminary source layer PSO may be removed and may be exposed to the outside.

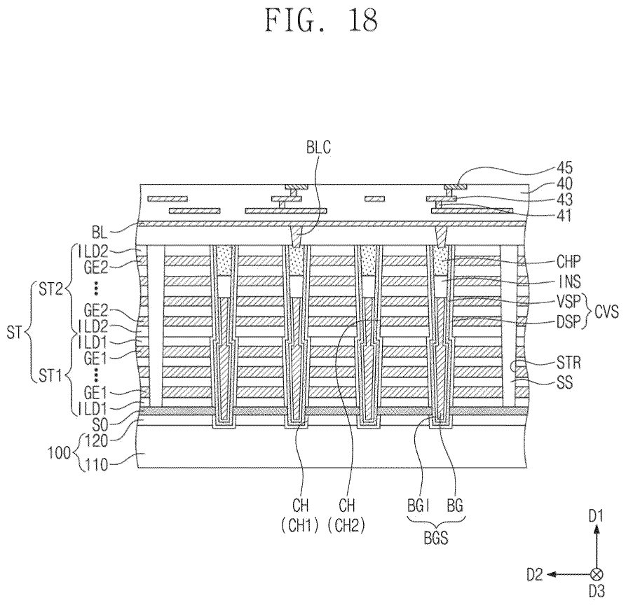

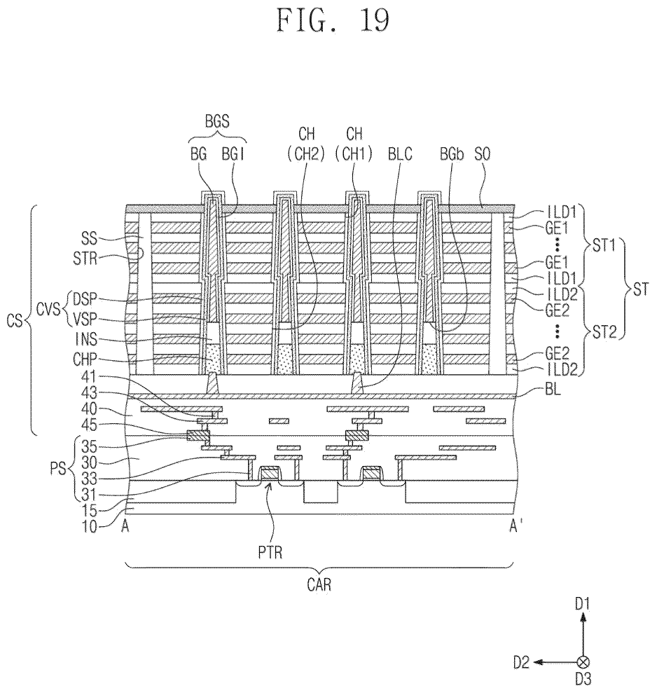

Referring to FIGS. 5 and 18, an isotropic etching process, in which the separation trench STR is used as a supply path, may be performed on the exposed portion of the preliminary source layer PSO. Thus, the second to fourth preliminary source layers may be removed. A portion of the data storage pattern DSP, which is adjacent to the preliminary source layer PSO in a horizontal direction, may be removed during this step. Thus, a portion of the vertical semiconductor pattern VSP may be exposed to the outside.

An additional source layer, which contains doped polysilicon, may be formed to fill an empty space, which is formed by removing the second to fourth preliminary source layers. The additional source layer, along with the first and fifth preliminary source layers, may constitute the source layer SO. The source layer SO may be formed to cover the exposed portion of the vertical semiconductor pattern VSP. Next, the etch protection layer EPL may be removed.

The processes from the formation process of the stack ST to the bonding process of the peripheral circuit structure PS and the cell array structure CS may be performed using the same fabrication method as described with reference to FIGS. 5, 13, and 14.

Referring to FIGS. 5 and 19, the first and second cell array substrates 110 and 120 may be removed, after the bonding of the peripheral circuit structure PS and the cell array structure CS. The removal process may be performed to have the same or similar features as those in the embodiment of FIGS. 5 and 14.

The source layer SO may be used as an etch stop layer in the removal process; for example, the source layer SO may not be removed or may be less removed, during the removal process. During the removal process on the second cell array substrate 120, the data storage pattern DSP of the cell vertical structure CVS may be exposed to the outside.

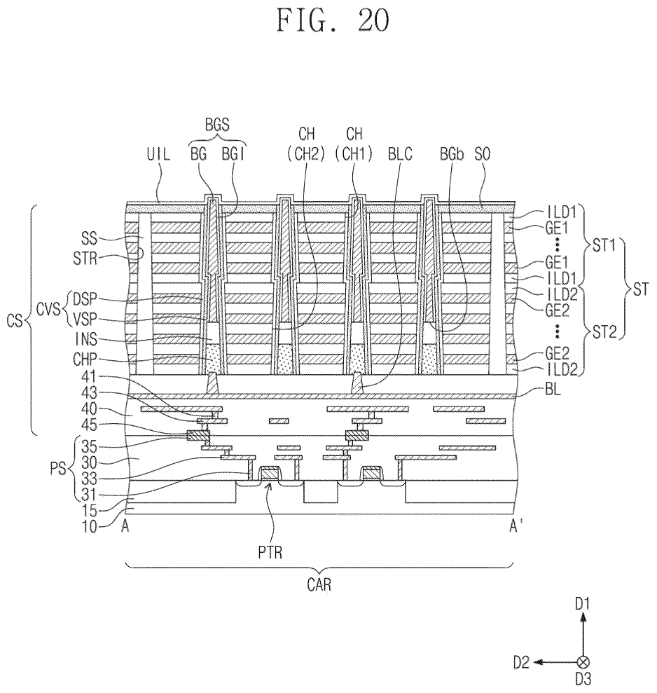

Referring to FIGS. 5 and 20, a removal process may be performed on the exposed portion of the data storage pattern DSP. In one or more embodiments, a portion of the vertical semiconductor pattern VSP, which contacts the exposed portion of the data storage pattern DSP, may be removed during the removal process. Thus, an upper portion of the back-gate structure BGS may be exposed to the outside.

The upper insulating layer UIL may be formed to conformally cover the top surface of the source layer SO and the exposed upper portion of the back-gate structure BGS.

Subsequent steps may be performed using the same fabrication method as described above, and in this case, the 3D semiconductor memory device may be fabricated to have the same structure as described with reference to FIG. 10.

According one or more embodiments, a back-gate electrode may be provided in a cell vertical structure covering an inner surface of a channel hole. Thus, a disturbance issue fin an unselected memory cell during writing and reading operations may be prevented from occurring. As a result, the reliability of the 3D semiconductor memory device may be improved.

At least one of the devices, units, components, modules, units, or the like represented by a block or an equivalent indication in the above embodiments including, but not limited to, FIG. 1B, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A three-dimensional (3D) semiconductor memory device, comprising:
a substrate;
a stack on the substrate, the stack comprising gate electrodes stacked in a first direction perpendicular to a bottom surface of the substrate;
a cell vertical structure penetrating the stack and extending in the first direction;
a source layer on a top surface of the stack;
a back-gate electrode in the cell vertical structure and extending in the first direction; and
a channel pad at a level lower than a bottom surface of the source layer and enclosed by the cell vertical structure,
wherein the back-gate electrode is spaced apart from the channel pad.

2. The 3D semiconductor memory device of claim 1, wherein each of the back-gate electrode and the channel pad comprises a conductive material.

3. The 3D semiconductor memory device of claim 1, further comprising an internal insulating pattern between the back-gate electrode and the channel pad,
wherein the back-gate electrode is spaced apart from the channel pad are by the internal insulating pattern.

4. The 3D semiconductor memory device of claim 1, wherein the cell vertical structure comprises a vertical semiconductor pattern and a data storage pattern,, and wherein the vertical semiconductor pattern is spaced apart from the back-gate electrode and contacts the channel pad.

5. The 3D semiconductor memory device of claim 1, further comprising a back-gate contact that contacts a top surface of the back-gate electrode.

6. The 3D semiconductor memory device of claim 5, wherein a width of the back-gate contact in a second direction increases in the first direction as the back-gate contact extends from the substrate in the first direction, and the second direction is perpendicular to the first direction.

7. The 3D semiconductor memory device of claim 5, further comprising an upper insulating layer between the source layer and the back-gate contact,
wherein the source layer is spaced apart from the back-gate contact by the upper insulating layer.

8. The 3D semiconductor memory device of claim 1, wherein the source layer contacts the cell vertical structure and is spaced apart from the back-gate electrode.

9. The 3D semiconductor memory device of claim 1, further comprising a bit line contact that contacts a bottom surface of the channel pad.

10. The 3D semiconductor memory device of claim 9, wherein a width of the bit line contact in a second direction decreases in the first direction as the bit line contact extends toward the substrate in the first direction, and the second direction is perpendicular to the first direction.

11. The 3D semiconductor memory device of claim 9, wherein the cell vertical structure is connected to the bit line contact through the channel pad.

12. A three-dimensional (3D) semiconductor memory device, comprising:
a substrate;
a stack on the substrate, the stack comprising gate electrodes stacked in a first direction perpendicular to a bottom surface of the substrate;
a cell vertical structure penetrating the stack and extending in the first direction;
a back-gate electrode in the cell vertical structure and extending in the first direction;
a back-gate contact that contacts a top surface of the back-gate electrode; and
a bit line at a level lower than a bottom surface of the back-gate electrode.

13. The 3D semiconductor memory device of claim 12, further comprising a channel pad below the back-gate electrode and enclosed by the cell vertical structure,
wherein the cell vertical structure is spaced apart from the back-gate electrode and contacts the channel pad.

14. The 3D semiconductor memory device of claim 13, further comprising an internal insulating pattern between the back-gate electrode and the channel pad,
wherein the back-gate electrode is spaced apart from the channel pad by the internal insulating pattern.

15. The 3D semiconductor memory device of claim 12, further comprising:
a source layer on a top surface of the stack; and
an upper insulating layer separating the source layer from the back-gate contact.

16. The 3D semiconductor memory device of claim 12, further comprising:
a channel pad below the back-gate electrode and enclosed by the cell vertical structure; and
a bit line contact between the channel pad and the bit line.

17. The 3D semiconductor memory device of claim 16, wherein a width of the back-gate contact in a second direction increases in the first direction as the back-gate contact extends away from the substrate, and the second direction is perpendicular to the first direction, and
wherein a width of the bit line contact in the second direction decreases in the first direction as the bit line contact extends toward the substrate.

18. An electronic system, comprising:
a three-dimensional semiconductor memory device; and
a controller connected to the three-dimensional semiconductor memory device through an input/output pad and configured to control the three-dimensional semiconductor memory device,
wherein the three-dimensional semiconductor memory device comprises:
a substrate;
a stack comprising gate electrodes stacked in a first direction perpendicular to a bottom surface of the substrate;
a cell vertical structure penetrating the stack and extending in the first direction;
a source layer on a top surface of the stack;
a back-gate electrode in the cell vertical structure and extending in the first direction; and
a channel pad at a level lower than a bottom surface of the source layer and enclosed by the cell vertical structure, and
wherein the back-gate electrode is spaced apart from the channel pad.

19. The electronic system of claim 18, further comprising:
a back-gate contact that contacts a top surface of the back-gate electrode; and
a bit line contact that contacts a bottom surface of the channel pad.

20. The electronic system of claim 18, further comprising an internal insulating pattern between the back-gate electrode and the channel pad,
wherein the back-gate electrode is spaced apart from the channel pad by the internal insulating pattern.
